(19) United States
(12) Patent Application Publication
(10) Pub. No.: US 2012/0098117 A1
(43) Pub. Date: Apr. 26, 2012

(54) POWER AND THERMAL DESIGN USING A COMMON HEAT SINK ON TOP OF HIGH THERMAL CONDUCTIVE RESIN PACKAGE

(75) Inventors: Tetsuo SATO, San Jose, CA (US); Nobuyoshi MATSUURA, Takasaki-shi (JP); Hiroki ANDO, Takasaki-shi (JP)

(73) Assignee: RENESAS TECHNOLOGY AMERICA, INC., Santa Clara, CA (US)

(21) Appl. No.: 12/910,087

(22) Filed: Oct. 22, 2010

(51) Int. Cl. H01L 23/34; H01L 21/58

(52) U.S. Cl. 257/707; 438/122; 257/E21.505; 257/E23.08

(57) ABSTRACT

An apparatus and method of manufacture may be provided for a package that can be coupled to a common heat sink without external electrical isolation. The apparatus, for example, can include a semi-conductor die comprising at least one electronic device. The apparatus can also include a frame on which a bottom side of the die is mounted, a bottom side of the frame being configured to attach to a printed circuit board. The apparatus can further include a high thermal conductivity resin molded onto a top side of the die.

### BACKGROUND

1. Field

A common heat sink can be used to remove excess thermal energy from two or more packages. The packages can be fabricated including a layer of high thermal conductive resin. The high thermal conductive resin can provide a thermal path between a terminal of a transistor and a common heat sink.

2. Description of the Related Art

Current computer systems typically use high power for central processing unit (CPU), graphics processing unit (GPU), and power supplies. This power can be supplied, for example, through a multi-phase or multi-rail voltage regulator (VR). In some cases, to drive high power supply, the voltage regulator uses a heat sink with airflow to remove generated heat from power driving devices.

FIG. 1 shows a block diagram of a non-isolated, multi-phase direct current to direct current (DC-DC) convertor for a personal computer (PC), including a high power voltage regulator (VR) with a heat sink. A DC-DC converter is one example of a power conversion device. To keep a junction temperature of a power conversion device, such as a DC-DC convertor, within safe operation, or to maintain the reliability of the package on the printed circuit board (PCB), the layout may employ a common heat sink on the top of several packages. The DC-DC converter as shown includes a pulse width modulator (PWM) integrated circuit (IC) supplying a signal to three drivers (DR1, DR2, and DR3), which operate transistor pairs to provide a high amperage output.

FIG. 2 shows a cross section of a plastic package power device with a heat sink on a printed circuit board. The heat sink is electrically isolated from each device by molded plastic. However, because of high thermal resistance between a die and the top of the package, most of the generated heat is ultimately removed from a back-side tab to the printed circuit board. Thus, the heat sink does not work very efficiently and may actually significantly increase the temperature of the printed circuit board.

Other package types may achieve lower thermal resistance from the junction to the top side. For example, FIGS. 3A and 3B illustrate a 5×6 mm both-side-cooling package for a power metal-oxide-semiconductor field-effect-transistor (MOSFET). This package, unlike the package illustrated in FIG. 2, has an exposed tab not only on the bottom side of the package, but also on the top side. The bottom side exposed tab, in this example, is the drain and the top side is the source. This package has a relatively low thermal resistance between the junction and the tab on the top side.

FIG. 4A illustrates a FET with a metal cap package, in cross-sectional view, and FIG. 4B illustrates a FET with a metal cap package, in perspective view. As can be seen from the figures, the source and gate terminals are exposed on the bottom side, and the drain is connected to a metal cap. This package, like the package shown in FIGS. 3A and 3B, has a relatively low thermal resistance between the junction and the tab on the top side.

FIG. 5 illustrates a cross section of a 5×6 mm both-side-cooling package with a heat sink. The top-side exposed metal (source) touches the heat sink. For an isolated DC-DC convertor, such as a buck convertor, the final circuit may involve a high-side MOSFET and a low-side MOSFET. The high-side source may be a switching node, while the low-side source may be ground (GND). Thus, a common heat sink is not possible, unless electric isolation is achieved.

FIGS. 6A and 6B illustrate a voltage regulator of a notebook PC, the voltage regulator being equipped with metal-cap FET package and a common heat sink, FIG. 6A illustrates a screwed down position and FIG. 6B illustrates an open position. The system employs a thermo pad that also works as electric isolation. The thermo pad, however, relies on a certain pressure to achieve good thermal conductivity. Accordingly, the thermal pad may need to be screwed down or clipped to mount the heat sink. In FIGS. 6A and 6B, two screws are used, although this is just one example.

It should be noted that the thermal pad itself may need to be patterned and shaped, as shown in FIG. 6B, which illustrates the patterned and shaped surface of the thermal pad. The thermal pad, in FIG. 6B is shown before being screwed down onto the four devices shown, whereas in FIG. 6A, the thermal pad is showed as screwed down.

### SUMMARY

In certain embodiments, an apparatus is provided including a semi-conductor die including at least one electronic device. The apparatus can also include a frame on which a bottom side of the die is mounted, a bottom side of the frame being configured to attach to a printed circuit board. The apparatus can further include a high thermal conductivity resin molded onto a top side of the die.

In further embodiments, an apparatus is provided including a plurality of high conductive resin packages, where each package includes a semi-conductor die including at least one electronic device, a frame on which a bottom side of the die is mounted, a bottom side of the frame being configured to attach to a printed circuit board, and a high thermal conductivity resin molded onto a top side of the die. The apparatus can also include a common heat sink attached to tops of the plurality of high conductive resin packages.

In additional embodiments, a method is provided including mounting a semi-conductor die including at least one electronic device by its bottom side to a frame, a bottom side of the frame being configured to attach to a printed circuit board. The method can also include molding a high thermal conductivity resin onto a top side of the die.

### BRIEF DESCRIPTION OF THE DRAWINGS

For proper understanding of the invention, reference should be made to the accompanying drawings, wherein:

FIG. 1 shows a block diagram of a non-isolated, multi-phase direct current to direct current (DC-DC) convertor for a personal computer (PC), including a high power voltage regulator (VR) with a heat sink.

FIG. 2 shows a cross section of a plastic package power device with a heat sink on a printed circuit board.

FIGS. 3A and 3B illustrate a 5×6 mm both-side-cooling package for a power metal-oxide-semiconductor field-effect-transistor (MOSFET).

FIG. 4A illustrates a FET with a metal cap package, in cross-sectional view.

FIG. 4B illustrates a FET with a metal cap package, in perspective view.

FIG. 5 illustrates a cross section of a 5×6 mm both-side-cooling package with a heat sink.

FIG. 6A illustrates a voltage regulator of a notebook PC, the voltage regulator being equipped with metal-cap FET package and a common heat sink, in a screwed down position.

FIG. 6B illustrates a voltage regulator of a notebook PC, the voltage regulator being equipped with metal-cap FET package and a common heat sink, in an open position.

FIG. 7 illustrates a relative comparison of thermal conductivity among resins, in accordance with an embodiment of the present invention.

FIG. 8A provides a view of a nano-structure of a high conductive resin, in accordance with an embodiment of the present invention, as portrayed by an electron diffraction microscope.

FIG. 8B provides a view of a nano-structure of a high conductive resin, in accordance with an embodiment of the present invention, in a stylized depiction.

FIG. 9 illustrates a driver MOSFET (DrMOS) metal clip package, in accordance with an embodiment of the present invention.

FIG. 10 illustrates a WPAK aluminum ribbon bonding structure, in accordance with an embodiment of the present invention.

FIG. 11 illustrates a high conductive resin package, including a power device with a common heat sink, in accordance with an embodiment of the present invention.

FIG. 12 illustrates a printed circuit board (PCB) layout and MOSFET power consumption for a thermal simulation, in accordance with an embodiment of the present invention.

FIG. 13 illustrates a heat sink model for a thermal simulation, in accordance with an embodiment of the present invention

FIG. 14 illustrates high-side/low-side junction temperature (Tj) vs. package thermal conductivity, in accordance with an embodiment of the present invention.

FIG. 15 illustrates DrMOS package thermal resistance, in accordance with an embodiment of the present invention.

FIG. 16 illustrates a DrMOS voltage regulator design comparison, in accordance with an embodiment of the present invention.

FIG. 17 illustrates a printed circuit board including a plurality of high conductive resin packages according to an embodiment of the present invention.

FIG. 18 illustrates a method, in accordance with an embodiment of the present invention.

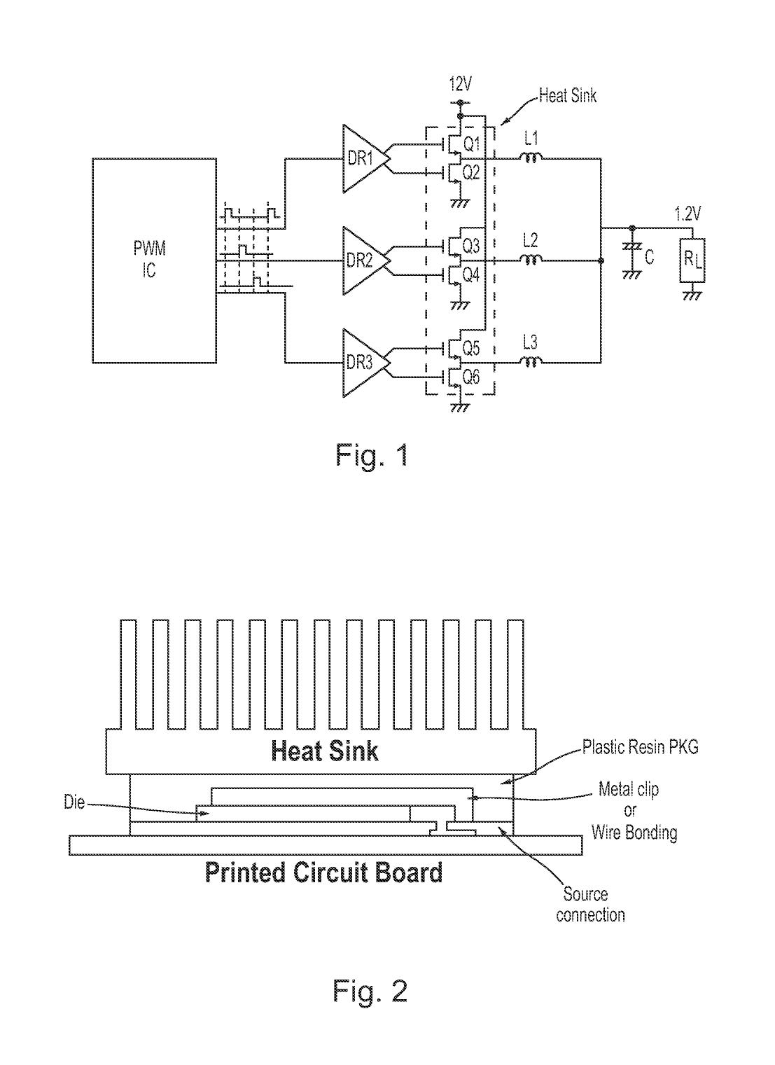

### DETAILED DESCRIPTION OF THE PREFERRED EMBODIMENT(S)

In a power delivery system, such as a voltage regulator (VR) or motor driver, high power drive devices are typically employed. The power devices consume power and heat up semiconductor dies on which the power devices are mounted. Removal of heat from the semiconductor dies and the power devices may be helpful for a variety of reasons. For example, removal of such heat may help to maintain safe operation and to ensure reliability.

Typically, one way to remove heat is using a heat sink. To take out the heat from both the printed circuit board and the heat sink sides, a both-sides-cooling package can be provided. A both-sides-cooling package can have exposed metal on the top of the package, and the metal can be connected to a part of the die as a lead frame. In many cases, multiple power devices with top side metal need electrical isolation. One approach to providing electrical isolation is to apply an electrically isolated thermal pad between the packages and a common heat sink. To achieve good thermal conductivity for the thermal pad, pressure can be applied using, for example, a screw-down or clip-down fastening system.

However, the use of a screw-down or clip-down fastening system can be avoided or minimized. For example, a high thermal conductivity resin can be used in the manufacture of a power device package. If the package employs a clip or aluminum ribbon structure, and a reasonable printed circuit board, heat sink size, and airflow condition, it may be possible to provide a suitable package including a thermal conductive resin having, for instance, over 3 W/mk of thermal conductivity. Thus, even a full molded package can be provided. There may be no need to consider electrical isolation between multiple power packages and the common heat sink. Furthermore, the package can be connected to the heat sink using a thermal conductive gel or glue instead of a thermal pad.

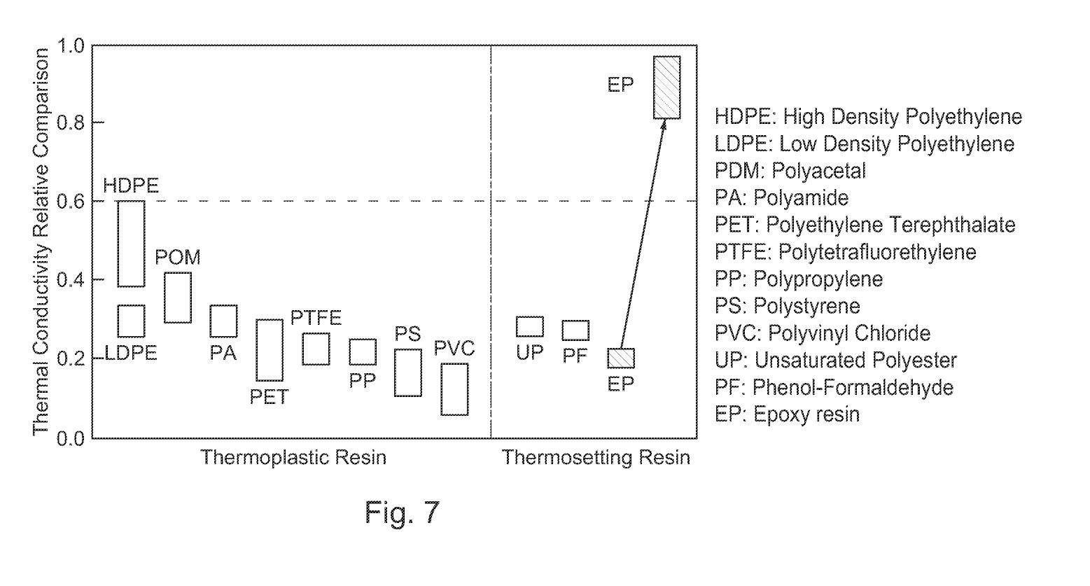

FIG. 7 illustrates a relative comparison of thermal conductivity among resins. The illustrated thermal conductivities are for thermoplastic resin and thermosetting resin. Using nano-materials, thermal conductive epoxy resin can have significantly higher thermal conductivity than previous resins.

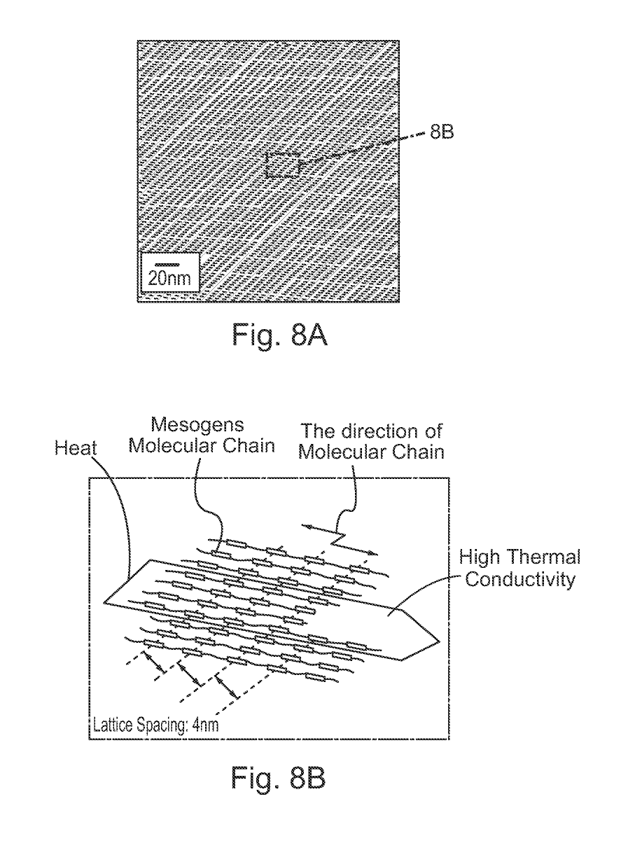

FIG. 8A provides a view of the nano-structure of a high conductive resin, as portrayed by an electron diffraction microscope. The liquid crystal epoxy resin, as can be seen, can have a self-aligning molecule structure. As shown in corresponding FIG. 8B, which provides a stylized depiction of the nano-structure of the high conductive resin, this self-aligning molecular structure may permit the resin to provide a high thermal conductivity.

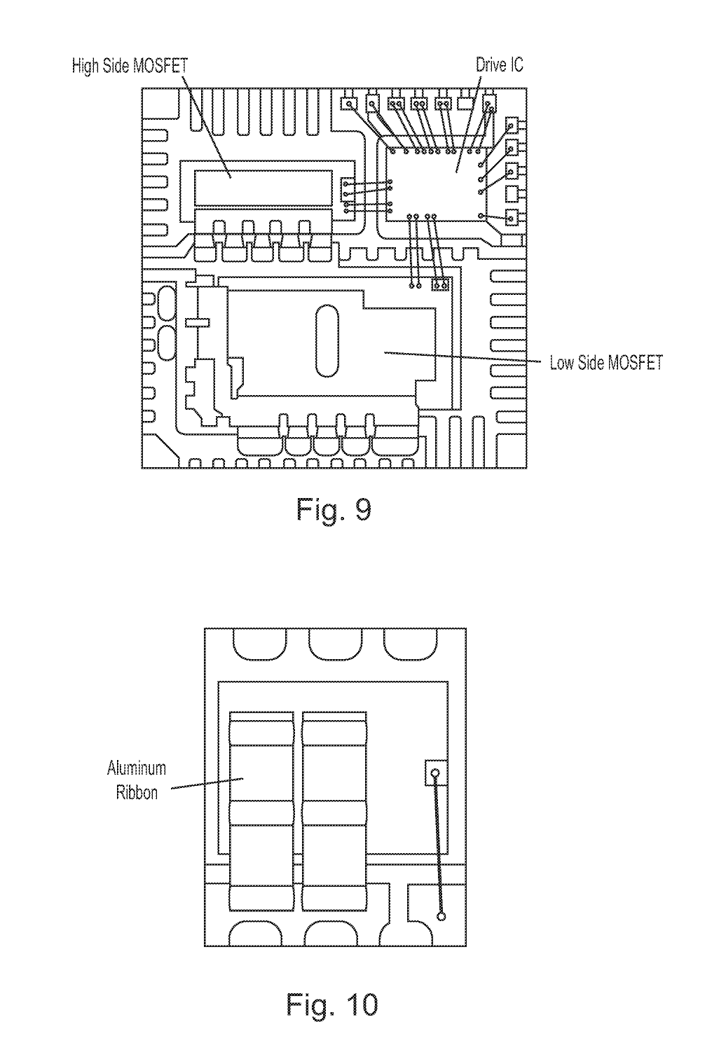

FIG. 9 illustrates an example of a driver MOSFET (DrMOS) metal clip package structure. A DrMOS can be provided with a metal clip for a variety of reasons. For example, the metal clip can reduce connection resistance from the power MOSFET to the pins. The metal clip can also reduce the thickness of the resin to the package top, and reduce the thermal resistance from the die to the top of the package.

This figure also shows a high-side MOSFET, a low-side MOSFET and a driving integrated circuit. In accordance with an embodiment, it may be particularly valuable to attach a common heat sink to the high-side and low-side MOSFETs.

FIG. 10 illustrates a WPAK aluminum ribbon bonding structure. This WPAK, as can be seen, uses an aluminum ribbon. The aluminum ribbon can reduce connection resistance between the power MOSFET and the pins. The aluminum ribbon can also reduce the thickness of the resin from the junction to the package top, and likewise, reduce the thermal resistance from the die to the top of the package. There are two aluminum ribbons shown with about three crimpings on each ribbon, but this is just an example. More or fewer ribbons may be used, and the manner of attaching the ribbons may be varied.

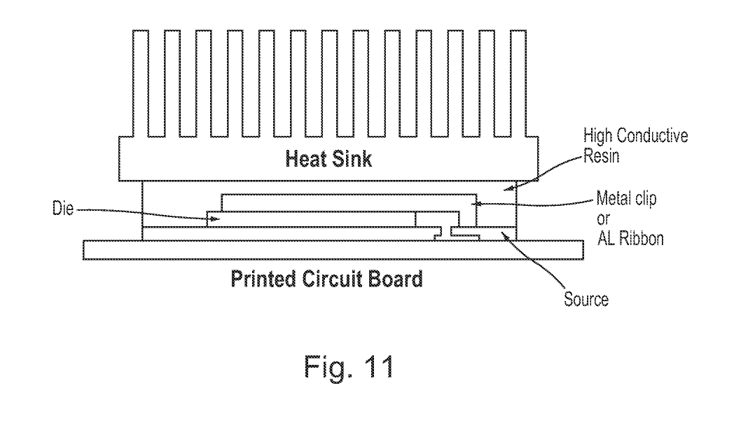

FIG. 11 illustrates a high conductive resin package, including a power device with a common heat sink. In this embodiment, a heat sink is used on the top of a power device, although it can also be applied over multiple power devices, which are not shown. The power device is plastic resin molded. In this example, at least a metal clip to the topside is covered by a thermal conductive resin having a thermal conductivity of, for instance, over 3 W/mk. The power device can have one or more exposed metal tabs on the bottom side for one heat path from the die on the bottom side to the air. A second heat path may exist to the top side of the package. The heat path may extend from the die to the metal clip, from the metal clip to the high thermal conductivity resin, from the high thermal conductivity resin to the heat sink, and finally from the heat sink to the air. The internal electric nodes of the package can be electrically isolated from the heat sink. Therefore, a common heat sink can be used on top of multiple power devices that have similar structure as the power device in this figure, even if the sources of the respective devices are not to be electrically connected to one another.

The metal clip shown in FIG. 11 may be any other metal plate structure, such as a metal ribbon. The metal clip is shown attached to a source, but the same configuration could be used to attach to a drain, if desired.

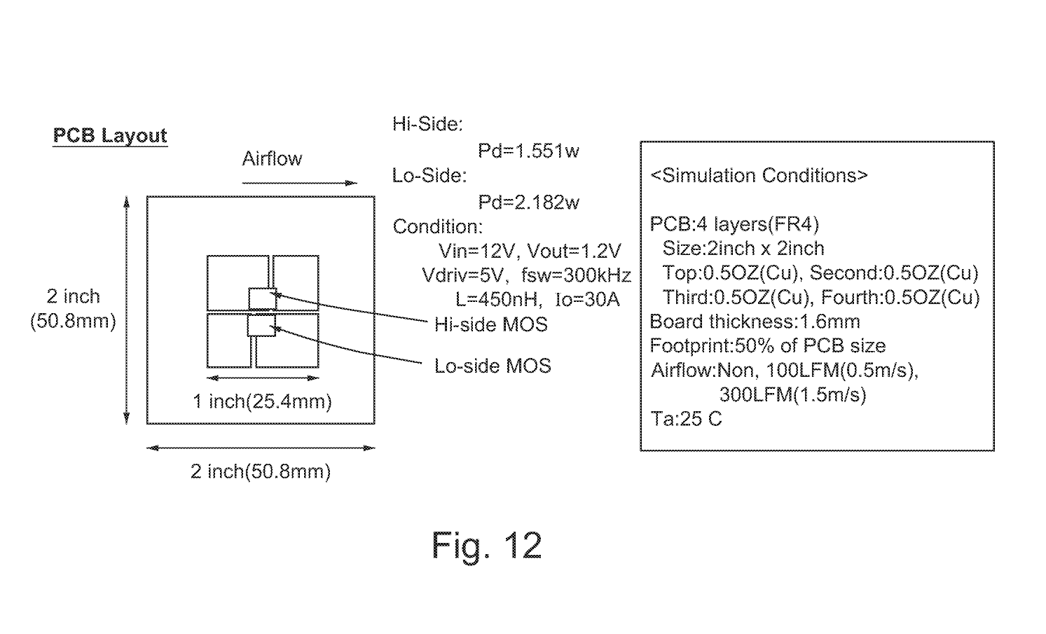

FIG. 12 shows a thermal design example using a thermal simulation. In this illustrated embodiment, the printed circuit board size is 2″×2″ and the copper pattern (footprint) size is 1″×1″. Moreover, the printed circuit board material is FR4 4-layers, and each layer has 0.5 oz copper. The board thickness is 1.6 mm. Two MOSFETs, one for a high-side and one for a low-side, are mounted on the board. Air with an ambient temperature Ta=25° C., 100 LFM airflow, blows from left to right. The MOSFETs can operate as a buck convertor the conditions Vin=12V, Vout=1.2V, Vdrive=5V, fsw=300 KHz, output inductor=450 nH and Io=30 A. Under this condition, the high-side MOSFET can consume Pd=1.551 W and the low-side MOSFET can consume Pd=2.182 W.

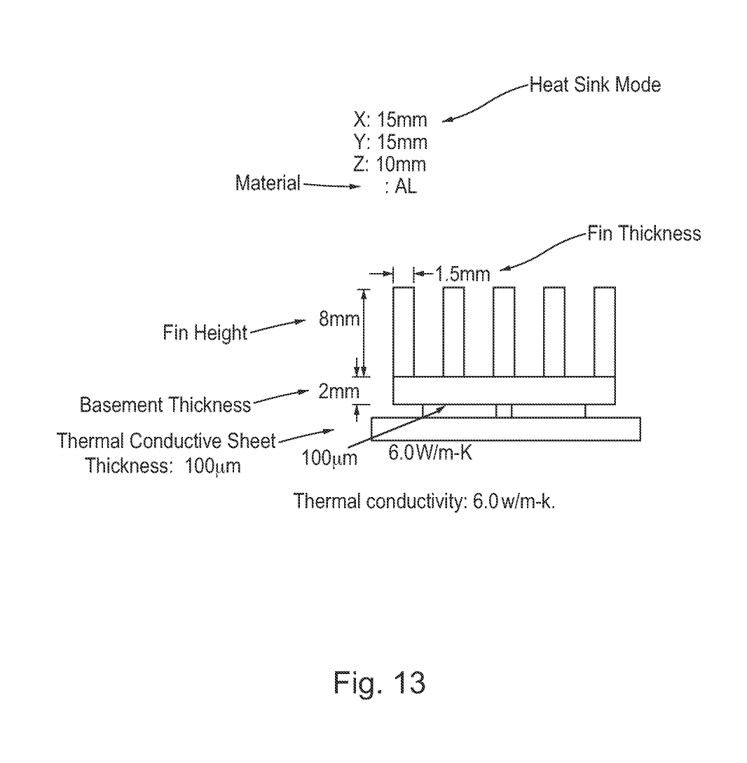

FIG. 13 shows a heat sink model for a design according to certain embodiments of the present invention. The material of the heat sink is aluminum, the size is X: 15 mm, Y: 15 mm, Z: 10 mm. The basement thickness is 2 mm, the fin height is 8 mm, and the fin thickness is 1.5 mm. This embodiment uses thermal conductive material between the packages and the fins, which has 6.0 W/mk thermal conductivity and 100 μm thickness.

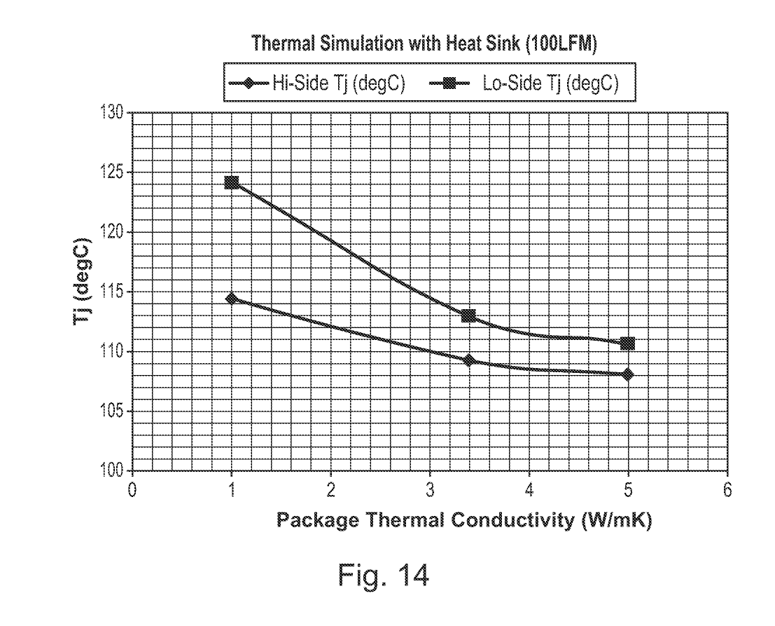

FIG. 14 shows a simulation result of high-side and low-side MOSFET junction temperature versus package thermal conductivity. Normal epoxy resin thermal conductivity for an integrated circuit (IC) package is around 1 W/mk or less, and the junction temperature drops steeply around 3 W/mk, then saturates. It may be possible to use epoxy resin that has a thermal conductivity higher than 3 W/mk.

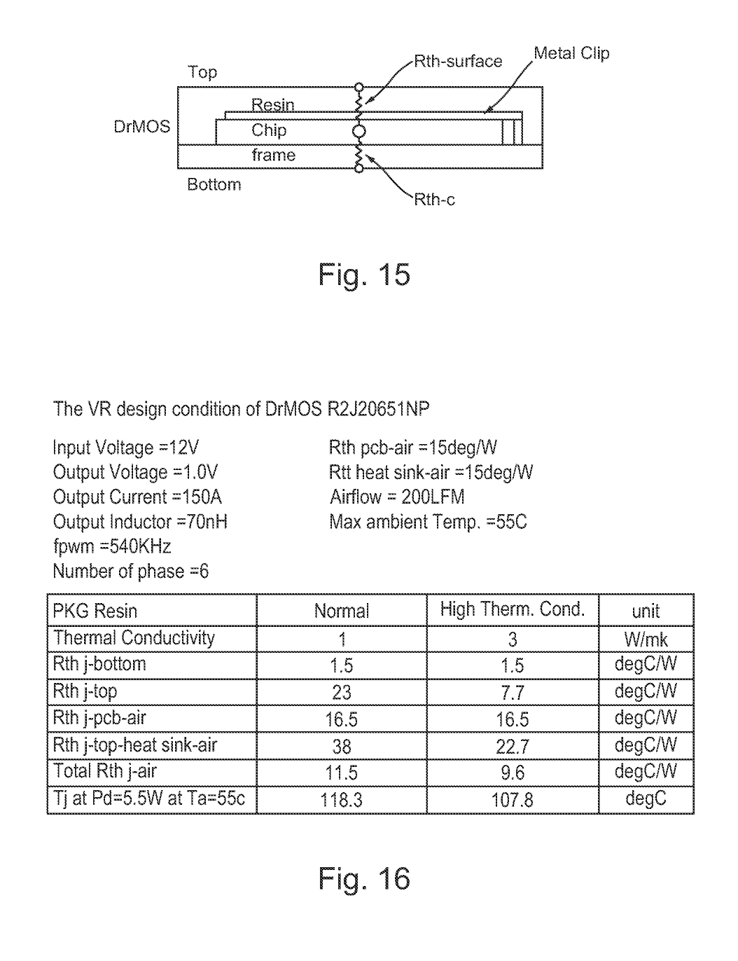

FIG. 15 is another junction temperature estimation case in DrMOS. This is a 6×6 mm quad flat no leads (QFN) package, with the cross-section shown in FIG. 15. The voltage regulator design example is Vin=12V, Vo=1.0V, Output Current=150 A total, Output Inductor=70 nH, and 6-phase operation. Thermal resistance between the printed circuit board and air is 15° C./W, while thermal resistance between the heat sink and air is 15° C./W, with Ta=55 C max and 200 LFM airflow. Under this condition, a DrMOS part number R2J20651NP consumes Pd=5.5 W.

FIG. 16 shows a DrMOS voltage regulator design comparison using a normal resin package (1 W/mk) versus a high thermal conductivity resin package (3 W/mk). The results are the results of calculation. Using the same heat sink on the top of the package, a high thermal conductive resin package reduces junction temperature 10.5° C. compared to a package that uses ordinary resin packaging.

In certain embodiments, the high thermal conductivity resin package may be composed of a different color resin than the resin used in a conventional package. This may permit circuit and thermal designer to differentiate between packages. Additionally, the selection of a lighter shade of gray for the high thermal conductive resin package may also simplify the design of the high thermal conductivity resin package, as it may avoid the need for the inclusion of additional coloring agents. Avoiding the addition of coloring agents may also help to ensure that the high thermal conductivity is maintained.

The above discussion has used a voltage regulator system as an illustrative example. However, the embodiments of the present invention are not limited to a voltage regulator system. Indeed, the packaging according to embodiments of the present invention can be use for many different kinds of thermal designs in which a common heat sink is used on top of multiple power consuming devices. Thus, for example, certain embodiments may be applicable to motor drivers, voice coil drivers, power interfaces, and other discrete devices and integrated circuits.

Power package clip or ribbon bonding, as mentioned above, not only can reduce the electrical connection resistance from die to pin or frame, but can also reduce the thickness of high conductive resin from die to top for lower thermal resistance. Furthermore, high thermal conductivity resin for power packaging may help to further enhance the low thermal resistance of the package.

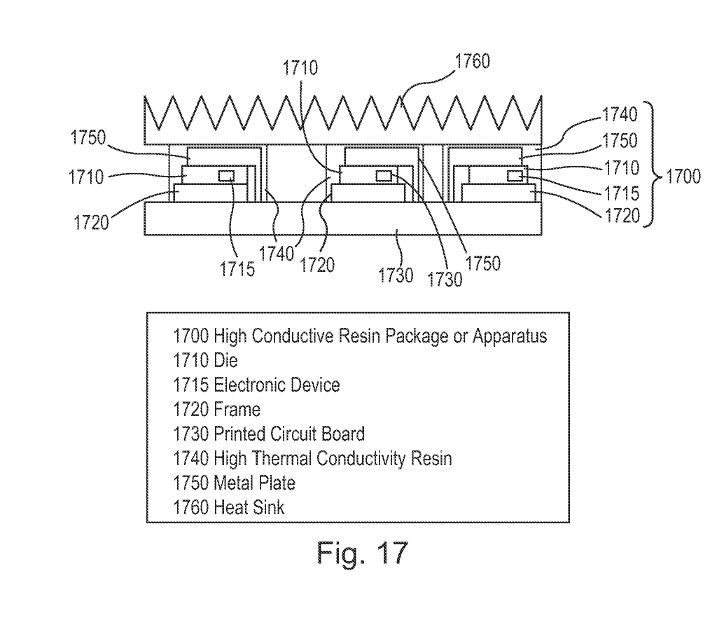

FIG. 17 illustrates a printed circuit board including a plurality of high conductive resin packages according to an embodiment of the present invention. The illustrated embodiment includes two or more high conductive resin packages or apparatuses 1700. Each apparatus 1700 can include a semi-conductor die 1710 comprising at least one electronic device 1715. The electronic device 1715 may be, for example a transistor or a similar electronic device manufactured in silicon. Many similar transistors may be included in the same electronic device 1715.

Each apparatus 1700 can also include a frame 1720 on which a bottom side of the die 1710 is mounted, a bottom side of the frame 1720 being configured to attach to a printed circuit board 1730. Each apparatus 1700 can further include a high thermal conductivity resin 1740 molded onto a top side of the die 1710. The high conductivity resin 1740 can have a thermal conductivity greater than 3 W/mk.

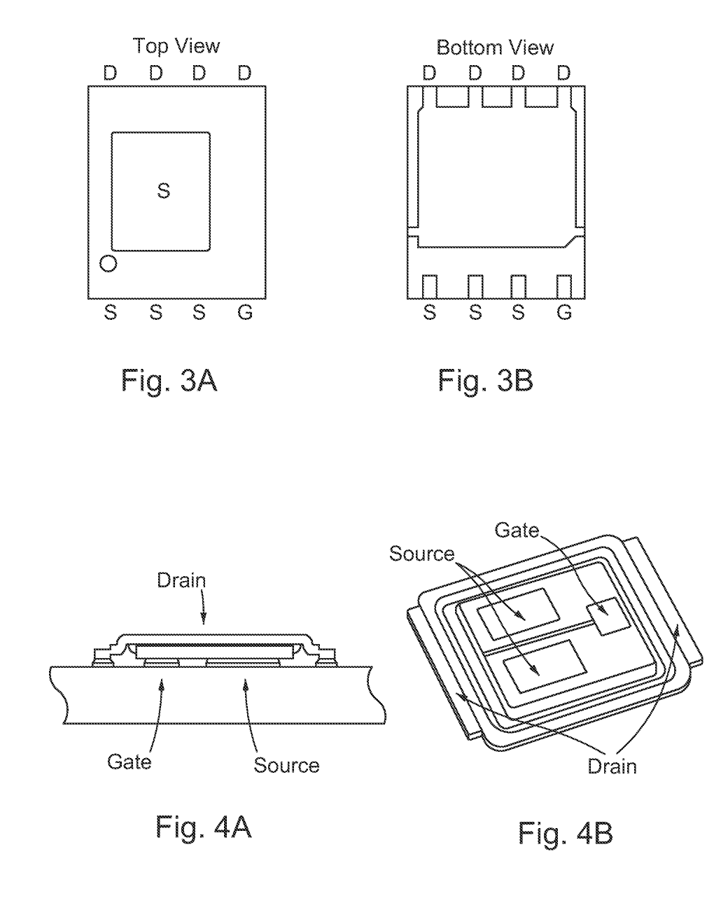

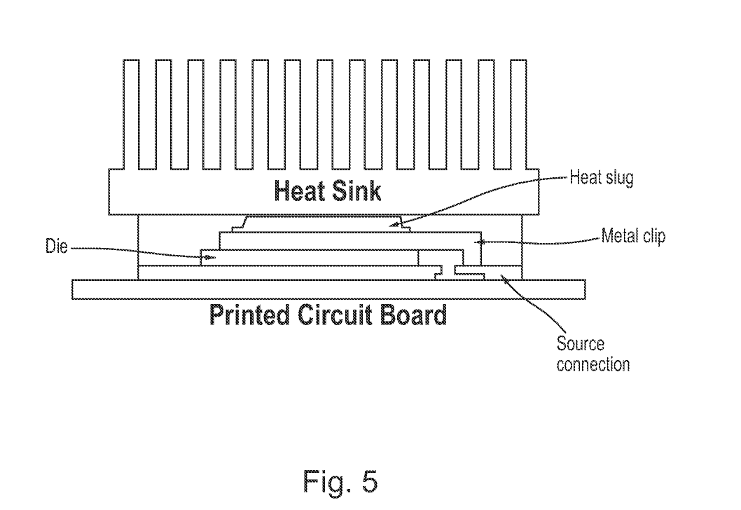

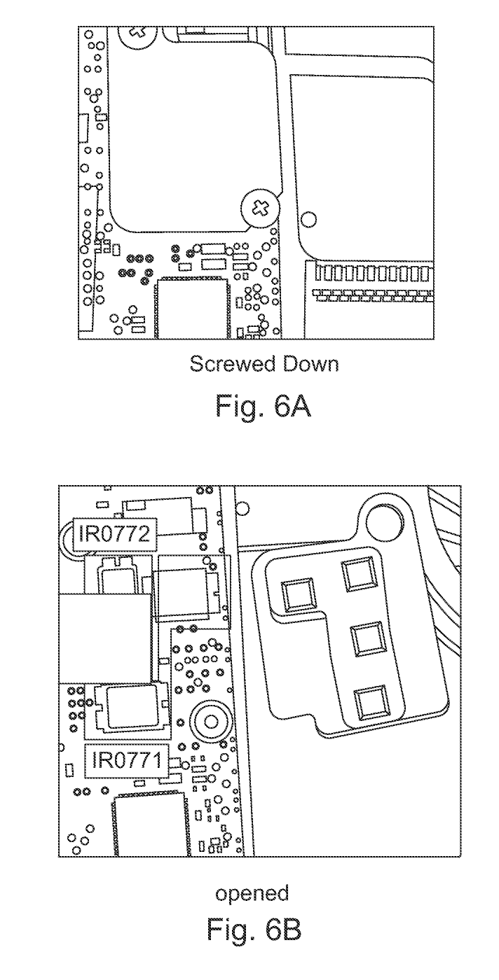

Each apparatus 1700 can also include an exposed tab on the bottom side of the frame 1720. Although the exposed tab is not shown, the configurations of FIGS. 3 and 4 may be used as examples of exposed tabs on the bottom side. Each apparatus 1700 can further include a metal plate 1750 on top of the die 1710, where the high thermal conductivity resin 1740 is molded on top of the metal plate 1750. A package color of each apparatus 1700 can be gray (this color is not explicitly illustrated in the drawings). The gray may be noticeably lighter in color than a conventional semiconductor device package.

The system can further include a common heat sink 1760 attached to tops of the apparatuses 1700. The apparatuses can be thermally coupled to the common heat sink without an additional electrical isolation material, such as silicon grease or glue.

The common heat sink 1760 may be constructed of a metal, such as aluminum, which has high thermal conductivity. Alternatively, a heat sink can be fabricated from the high thermal conductivity molded resin. In a further alternative embodiment, the common heat sink 1760 and the high thermal conductivity resin 1740 may be configured to interface with one another, such that the heat sink can be held to the high thermal conductivity resin 1740 by an interference fit, either directly or with a small amount of adhesive assisting the connection between the common heat sink 1760 and the high thermal conductivity resin 1740.

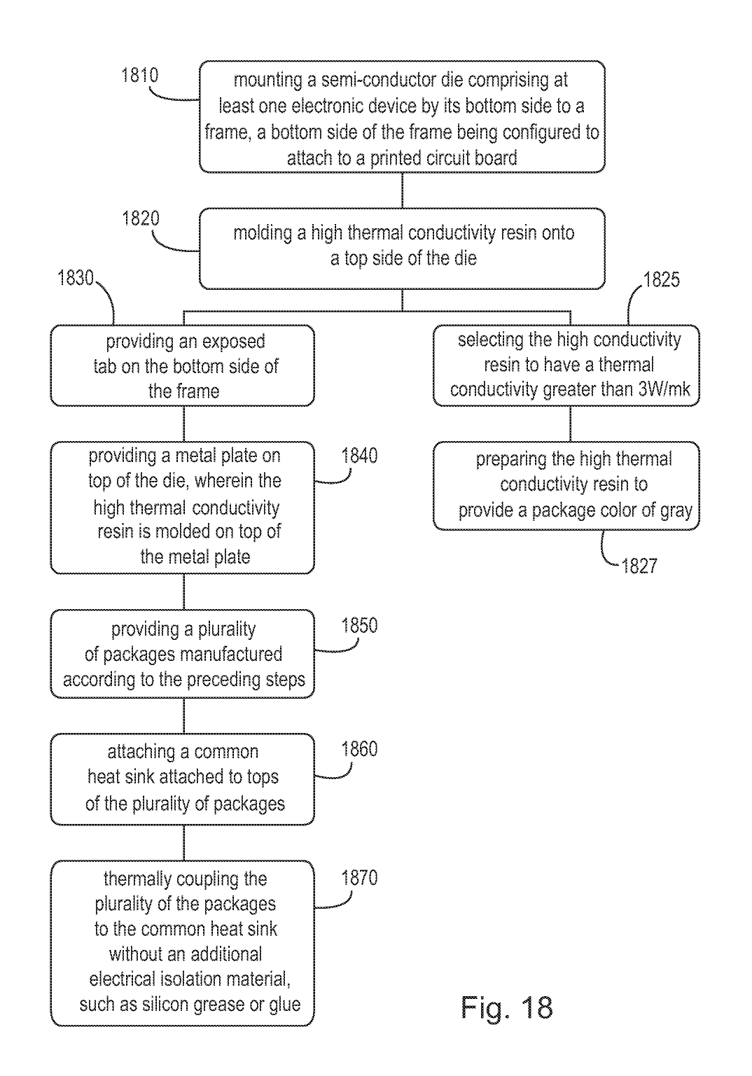

FIG. 18 illustrates a method according to the present invention. The method of FIG. 18 includes mounting 1810 a semi-conductor die including at least one electronic device by its bottom side to a frame, a bottom side of the frame being configured to attach to a printed circuit board. The method also includes molding 1820 a high thermal conductivity resin onto a top side of the die.

The method can further include selecting 1825 the high conductivity resin to have a thermal conductivity greater than 3 W/mk. The method can additionally include providing 1830 an exposed tab on the bottom side of the frame. The method can also include providing 1840 a metal plate on top of the die, where the high thermal conductivity resin is molded on top of the metal plate. The method can further include preparing 1827 the high thermal conductivity resin to provide a package color of gray.

The method can additionally include providing 1850 a plurality of packages manufactured according to the preceding steps and attaching 1860 a common heat sink attached to tops of the plurality of packages. The method can also include thermally coupling 1870 the plurality of the packages to the common heat sink without an additional electrical isolation material, such as silicon grease or glue.

One having ordinary skill in the art will readily understand that the invention as discussed above may be practiced with steps in a different order, and/or with hardware elements in configurations which are different than those which are disclosed. Therefore, although the invention has been described based upon these preferred embodiments, it would be apparent to those of skill in the art that certain modifications, variations, and alternative constructions would be apparent, while remaining within the spirit and scope of the invention. In order to determine the metes and bounds of the invention, therefore, reference should be made to the appended claims.

We claim:

1. An apparatus, comprising:
a semi-conductor die comprising at least one electronic device;
a frame on which a bottom side of the die is mounted, a bottom side of the frame being configured to attach to a printed circuit board; and
a high thermal conductivity resin molded onto a top side of the die.

2. The apparatus of claim 1, wherein the high conductivity resin has a thermal conductivity greater than 3 W/mk.

3. The apparatus of claim 1, further comprising:
an exposed tab on the bottom side of the frame.

4. The apparatus of claim 1, wherein the apparatus further comprises a metal plate on top of the die, wherein the high thermal conductivity resin is molded on top of the metal plate.

5. The apparatus of claim 1, wherein a package color of the apparatus is other than black.

6. An apparatus, comprising:
a plurality of high conductive resin packages, wherein each package comprises a semi-conductor die comprising at least one electronic device, a frame on which a bottom side of the die is mounted, a bottom side of the frame being configured to attach to a printed circuit board, and a high thermal conductivity resin molded onto a top side of the die; and
a common heat sink attached to tops of the plurality of high conductive resin packages.

7. The apparatus of claim 6, wherein the plurality of high conductive resin packages are thermally coupled to the common heat sink without an additional electrical isolation material.

8. A method, comprising:
mounting a semi-conductor die comprising at least one electronic device by its bottom side to a frame, a bottom side of the frame being configured to attach to a printed circuit board; and
molding a high thermal conductivity resin onto a top side of the die.

9. The method of claim 8, further comprising:
selecting the high conductivity resin to have a thermal conductivity greater than 3 W/mk.

10. The method of claim 8, further comprising
providing an exposed tab on the bottom side of the frame.

11. The method of claim 8, wherein the method further comprises:
providing a metal plate on top of the die, wherein the high thermal conductivity resin is molded on top of the metal plate.

12. The method of claim 8, further comprising:
preparing the high thermal conductivity resin to provide a package color other than black.

13. The method of claim 8 further comprising:
providing a plurality of packages manufactured according to claim 8; and
attaching a common heat sink attached to tops of the plurality of packages.

14. The method of claim 13, further comprising:
thermally coupling the plurality of the packages to the common heat sink without an additional electrical isolation material.
